(19) United States
(12) Patent Application Publication
(10) Pub. No.: US 2016/0020364 A1
(43) Pub. Date: Jan. 21, 2016

(54) TWO STEP TRANSPARENT CONDUCTIVE FILM DEPOSITION METHOD AND GAN NANOWIRE DEVICES MADE BY THE METHOD

(71) Applicant: GLO AB, Lund (SE)

(72) Inventor: Scott Brad HERNER, LAFAYETTE, CO (US)

(21) Appl. No.: 14/772,353

(22) PCT Filed: Mar. 12, 2014
(86) PCT No.: PCT/US2014/024268

§ 371 Date: Sep. 2, 2015

Related U.S. Application Data
(60) Provisional application No. 61/787,299, filed on Mar. 15, 2013.

(51) Int. Cl. H01L 33/42; H01L 33/62; H01L 33/06; H01L 33/00; H01L 33/32

(52) U.S. Cl. CPC H01L 33/42; H01L 33/0075; H01L 33/32; H01L 33/06; H01L 33/62; H01L 2933/0016; H01L 2933/0066

(57) ABSTRACT

A method of making a semiconductor device includes depositing a first transparent conductive film (TCF) contact layer on a sidewall of a III-nitride semiconductor nanostructure by evaporation, and depositing a second TCF contact layer over the first TCF contact layer by sputtering or chemical vapor deposition (CVD).

### RELATED APPLICATION

This application claims the benefit of priority to U.S. Provisional Application No. 61/787,299 filed on Mar. 15, 2013, the entire teachings of which are incorporated herein by reference.

### FIELD

The embodiments of the invention are directed generally to semiconductor devices, such as nanowire light emitting diodes (LED), and specifically to nanowire LEDs with a two step indium tin oxide ohmic contact deposition.

### BACKGROUND

Nanowire light emitting diodes (LED) are of increasing interest as an alternative to planar LEDs. In comparison with LEDs produced with conventional planar technology, nanowire LEDs offer unique properties due to the one-dimensional nature of the nanowires, improved flexibility in materials combinations due to less lattice matching restrictions and opportunities for processing on larger substrates.

### SUMMARY

A method of making a semiconductor device includes depositing a first transparent conductive film (TCF) contact layer on a sidewall of a III-nitride semiconductor nanostructure by evaporation, and depositing a second TCF contact layer over the first TCF contact layer by sputtering or chemical vapor deposition (CVD).

### BRIEF DESCRIPTION OF THE DRAWINGS

FIG. 1 schematically illustrates a side cross sectional view of a basis of a nanowire LED in accordance with embodiments of the invention.

FIG. 2 schematically illustrates a side cross sectional view of a nanowire LED structure on a buffer layer in accordance with embodiments of the invention.

FIG. 3A is a side cross sectional view of a nanowire having an indium tin oxide (ITO) contact formed only by evaporation; FIG. 3B is a side cross sectional view of a nanowire having an ITO contact formed by evaporation followed by sputtering.

FIG. 4A is a plot of current versus voltage of nanowire devices having an ITO contact formed only by evaporation; FIG. 4B is a plot of current versus voltage of nanowire devices with an ITO contact formed by evaporation followed by sputtering.

FIG. 5 is a probability plot of the voltage at 1 mA current for two substrates with approximately 500 devices tested on each substrate.

FIG. 6 is a side cross sectional view of a nanowire having a first transparent film composed of ITO deposited by evaporation, and a second transparent film composed of FTO deposited by chemical vapor.

FIG. 7 is a probability plot of the voltage at 10 mA current for two substrates with approximately 500 devices tested on each substrate. One substrate has a contact composed of evaporated ITO (1^{st} film) and CVD FTO (2^{nd} film), and the other substrate has a contact composed of CVD FTO only.

### DETAILED DESCRIPTION OF THE EMBODIMENTS OF THE INVENTION

In the art of nanotechnology, nanowires are usually interpreted as nanostructures having a lateral size (e.g., diameter for cylindrical nanowires or width for pyramidal or hexagonal nanowires) of nano-scale or nanometer dimensions, whereas its longitudinal size is unconstrained. Such nanostructures are commonly also referred to as nanowhiskers, one-dimensional nano-elements, nanorods, nanotubes, etc. The nanowires can have a diameter or width of up to about 2 micron. The small size of the nanowires provides unique physical, optical and electronic properties. These properties can for example be used to form devices utilizing quantum mechanical effects (e.g., using quantum wires) or to form heterostructures of compositionally different materials that usually cannot be combined due to large lattice mismatch. As the term nanowire implies, the one dimensional nature may be associated with an elongated shape. Since nanowires may have various cross-sectional shapes, the diameter is intended to refer to the effective diameter. By effective diameter, it is meant the average of the major and minor axis of the cross-section of the structure.

All references to upper, top, lower, downwards etc. are made as considering the substrate being at the bottom and the nanowires extending upwards from the substrate. Vertical refers to a direction perpendicular to the plane formed by the substrate, and horizontal to a direction parallel to the plane formed by the substrate. This nomenclature is introduced for the easy of understanding only, and should not be considered as limiting to specific assembly orientation etc.

Any suitable nanowire LED structure as known in the art may be used in the methods of the invention. Nanowire LEDs are typically based on one or more pn- or p-i-n-junctions. The difference between a pn junction and a p-i-n-junction is that the latter has a wider active region. The wider active region allows for a higher probability of recombination in the i-region. Each nanowire comprises a first conductivity type (e.g., n-type) nanowire core and an enclosing second conductivity type (e.g., p-type) shell for forming a pn or pin junction that in operation provides an active region for light generation. While the first conductivity type of the core is described herein as an n-type semiconductor core and the second conductivity type shell is described herein as a p-type semiconductor shell, it should be understood that their conductivity types may be reversed.

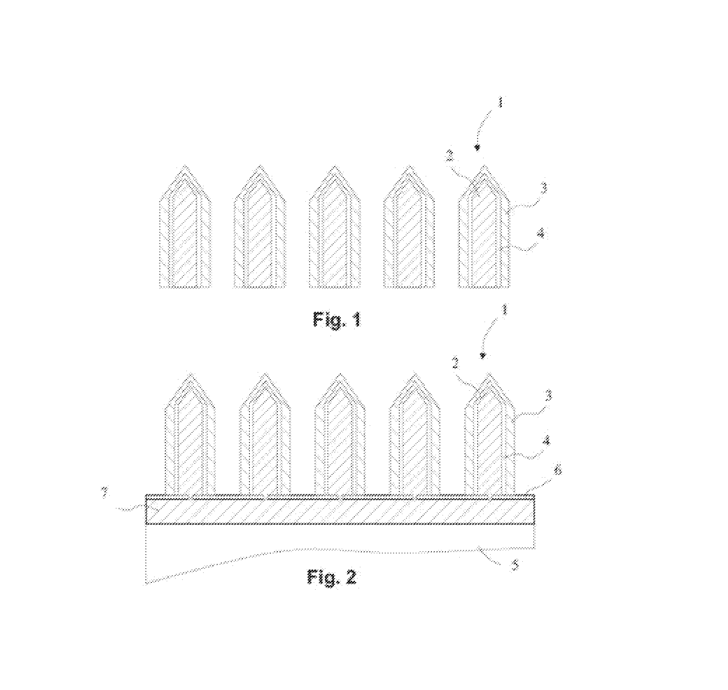

FIG. 1 schematically illustrates the basis for a nanowire LED structure that is modified in accordance with embodiments of the invention. In principle, one single nanowire is enough for forming a nanowire LED, but due to the small size, nanowires are preferably arranged in arrays comprising hundreds, thousands, tens of thousands, or more, of nanowires side by side to form the LED structure. For illustrative purposes the individual nanowire LED devices will be described herein as being made up from nanowire LEDs 1 having an n-type nanowire core 2 and a p-type shell 3 at least partly enclosing the nanowire core 2 and an intermediate active region 4, which may comprise a single intrinsic or lightly doped (e.g., doping level below 10¹⁶ cm⁻³) semiconductor layer or one or more quantum wells, such as 3-10 quantum wells comprising a plurality of semiconductor layers of different band gaps. However, for the purpose of embodiments of the invention nanowire LEDs are not limited to this. For example the nanowire core 2, the active region 4 and the p-type shell 3 may be made up from a multitude of layers or segments. In alternative embodiments, only the core 2 may comprise a nanostructure or nanowire by having a width or diameter below 2 micron, while the shell 3 may have a width or diameter above one micron.

The III-V semiconductors are of particular interest due to their properties facilitating high speed and low power electronics and optoelectronic devices such as lasers and LEDs. The nanowires can comprise any semiconductor material, and suitable materials for the nanowire include but are not limited to: GaAs (p), InAs, Ge, ZnO, InN, GaInN, GaNAlGaInN, BN, InP, InAsP, GaInP, InGaP:Si, InGaP:Zn, GaInAs, AlInP, GaAlInP, GaAlInAsP, GaInSb, InSb, Si. Possible donor dopants for e.g. GaP are Si, Sn, Te, Se, S, etc, and acceptor dopants for the same material are Zn, Fe, Mg, Be, Cd, etc. It should be noted that the nanowire technology makes it possible to use nitrides such as GaN, InN and AN, which facilitates fabrication of LEDs emitting light in wavelength regions not easily accessible by conventional technique. Other combinations of particular commercial interest include, but are not limited to GaAs, GaInP, GaAlInP, GaP systems. Typical doping levels range from 10¹⁸ to 10²⁰ cm⁻³. A person skilled in the art is though familiar with these and other materials and realizes that other materials and material combinations are possible.

Preferred materials for nanowire LEDs are III-V semiconductors such as a III-nitride semiconductor (e.g., GaN, AlInGaN, AlGaN and InGaN, etc.) or other semiconductor (e.g., InP, GaAs). In order to function as a LED, the n-side and p-side of each nanowire LED 1 has to be contacted, and the present invention provides methods and compositions related to contacting the n-side and the p-side of the nanowires in a LED structure.

Although the exemplary fabrication method described herein preferably utilizes a nanowire core to grow semiconductor shell layers on the cores to form a core-shell nanowire, as described for example in U.S. Pat. No. 7,829,443, to Seifert et al., incorporated herein by reference for the teaching of nanowire fabrication methods, it should be noted that the invention is not so limited. For example, in alternative embodiments, only the core may constitute the nanostructure (e.g., nanowire) while the shell may optionally have dimensions which are larger than typical nanowire shells. Furthermore, the device can be shaped to include many facets, and the area ratio between different types of facets may be controlled. This is exemplified by the “pyramid” facets and the vertical sidewall facets. The LEDs can be fabricated so that the emission layer formed on templates with dominant pyramid facets or sidewall facets. The same is true for the contact layer, independent of the shape of the emission layer.

FIG. 2 illustrates an exemplary structure that provides a support for the nanowires. By growing the nanowires on a growth substrate 5, optionally using a growth mask, or dielectric masking layer, 6 (e.g., a nitride layer, such as silicon nitride dielectric masking layer) to define the position and determine the bottom interface area of the nanowires, the substrate 5 functions as a carrier for the nanowires that protrude from the substrate 5, at least during processing. The bottom interface area of the nanowires comprises the root area of the core 2 inside each opening in the dielectric masking layer 6. The substrate 5 may comprise different materials, such as III-V or II-VI semiconductors, Si, Ge, Al₂O₃, SiC, Quartz, glass, etc., as discussed in Swedish patent application SE 1050700-2 (assigned to GLO AB), which is incorporated by reference herein in its entirety. Other suitable materials for the substrate include, but are not limited to: GaAs, GaP, GaP:Zn, GaAs, InAs, InP, GaN, GaSb, ZnO, InSb, SOI (silicon-on-insulator), CdS, ZnSe, CdTe. In one embodiment, the nanowire cores 2 are grown directly on the growth substrate 5.

Preferably, the substrate 5 is also adapted to function as a current transport layer connecting to the n-side of each nanowire LED 1. This can be accomplished by having a substrate 5 that comprises a semiconductor buffer layer 7 arranged on the surface of the substrate 5 facing the nanowire LEDs 1, as shown in FIG. 2, by way of example a III-nitride layer, such as a GaN and/or AlGaN buffer layer 7 on a Si substrate 5. The buffer layer 7 is usually matched to the desired nanowire material, and thus functions as a growth template in the fabrication process. For an n-type core 2, the buffer layer 7 is preferably also doped n-type. The buffer layer 7 may comprise a single layer (e.g., GaN), several sublayers (e.g., GaN and AlGaN) or a graded layer which is graded from high Al content AlGaN to a lower Al content AlGaN or GaN.

A first, transparent electrode (e.g., a p-side electrode), such as a transparent conductive oxide (TCO), such as indium tin oxide, fluorine doped tin oxide or aluminum zinc oxide, is formed over the shells 3, as will be described below. A second electrode layer (e.g., n-side electrode) electrically connects to the n-type nanowire cores 2. The second electrode may be formed on the bottom of the substrate 5 if the substrate 5 is a semiconductor (e.g., silicon or GaN) or conductive substrate. Alternatively, the second electrode may contact the n-type semiconductor buffer layer 7 on the substrate 5 from the top side in a region where the nanowires and the first, transparent electrode have been removed.

The growth of nanowires can be achieved by utilizing methods described in the U.S. Pat. Nos. 7,396,696, 7,335,908, and 7,829,443, and WO201014032, WO2008048704 and WO 2007102781, all of which are incorporated by reference in their entirety herein.

It should be noted that the nanowire LEDs 1 may comprise several different materials (e.g., GaN core, GaN/InGaN multiple quantum well active region and AlGaN shell having a different In to Ga ratio than the active region). In general the substrate 5 and/or the buffer layer 7 are referred to herein as a support or a support layer for the nanowires. In certain embodiments, a conductive layer (e.g., a mirror or transparent contact) may be used as a support instead of or in addition to the substrate 5 and/or the buffer layer 7. Thus, the term “support layer” or “support” may include any one or more of these elements.

The use of sequential (e.g., shell) layers gives that the final individual device (e.g., a pn or pin device) may have a shape anywhere between a pyramid or tapered shape (i.e., narrower at the top or tip and wider at the base) and pillar shaped (e.g., about the same width at the tip and base) with circular or hexagonal or other polygonal cross section perpendicular to the long axis of the device. Thus, the individual devices with the completed shells may have various sizes. For example, the sizes may vary, with base widths ranging from 100 nm to several (e.g., 5) μm, such as 100 nm to below 2 micron, and heights ranging from a few 100 nm to several (e.g., 10) μm.

The above description of an exemplary embodiment of a LED structure will serve as a basis for the description of the methods and compositions of the invention; however, it will be appreciated that any suitable nanowire LED structure or other suitable nanowire structure may also be used in the methods and compositions, with any necessary modifications as will be apparent to one of skill in the art, without departing from the invention.

A transparent conductive oxide, such as indium tin oxide (ITO) may be used to form an ohmic transparent contact to p-type GaN. Conventionally, ITO contacts are made by either evaporation or sputtering. Other transparent conductive films may be deposited by evaporation, sputtering, or chemical vapor. ITO deposited by standard sputtering techniques, or other TCFs by CVD, on p-type GaN can yield a poor contact. This poor contact results in increased voltage operation and increased power consumption in GaN nanowire LED devices.

ITO deposited by evaporation techniques make a good ohmic contact. However, the inventors have discovered that for nanowire devices, such as the nanowire LEDs described above, ITO deposited by evaporation-only results in two problems—mechanical and electrical stability issues—that develop later in fabrication. The inventors have discovered that use of a two step ITO deposition process effectively addresses these two issues. Embodiments of the two step process include deposition of a thinner layer of evaporated ITO followed by deposition of a thicker layer of sputtered ITO using sputtering.

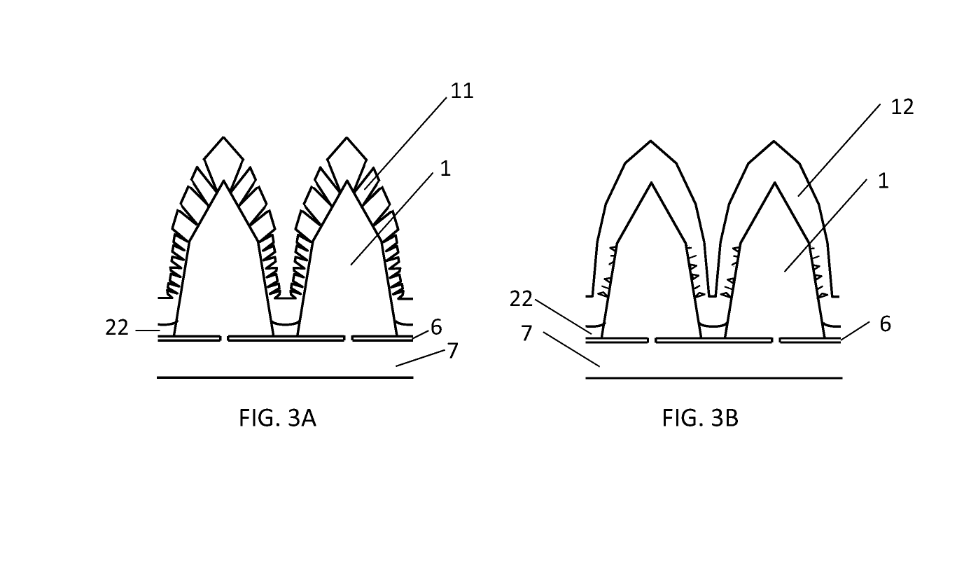

FIG. 3A is a side cross sectional view of a nanowire device having an 800 nm ITO contact 11 formed only by evaporation over a nanowire 1 having an insulating film 22 (e.g. spin on glass) at the base of the nanowire. However, as can be seen in FIG. 3A, the sidewalls of the nanowire device exhibit a low density of ITO 11 compared to the density ITO 11 in between the nanowire devices.

In contrast, FIG. 3B is a side cross sectional view of a nanowire device having an ITO contact 12 formed by evaporation followed by sputtering over a nanowire 1 having an insulating film 22 (e.g. spin on glass) at the base of the nanowire. In this embodiment, a first ITO sublayer is evaporated to produce a 200 nm thick contact sublayer (i.e., seed layer) followed by sputtering a 600 nm thick second ITO sublayer (i.e., overlying contact layer) on the first sublayer to produce a contact layer. In general, the evaporated seed layer may be 10-300 nm thick and the sputtered ITO layer may be 50-800 nm thick, such that a thickness ratio of the evaporated to the sputtered ITO layers may be from 1:80 to 6:1, such as 1:3 and the total thickness of both layers may be 450-800 nm.

Unlike the example illustrated in FIG. 3A, the sidewalls of the nanowire devices 1 in this embodiment have relatively high density ITO layer 12 compared to evaporated-only ITO contact layer 11 illustrated in FIG. 3A. The ITO layer 12 density is about the same on the sidewalls of the nanowire devices and in the region between the nanowire devices.

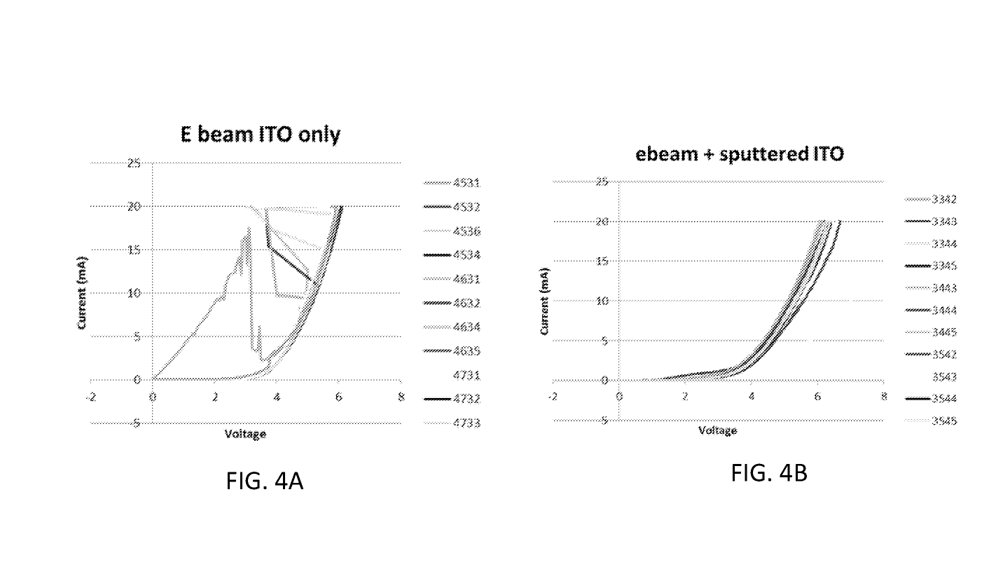

FIGS. 4A and 4B are plots of current versus voltage of nanowire devices having an ITO contact formed only by evaporation and nanowire devices with an ITO contact formed by evaporation followed by sputtering, respectively. Of the 11 devices with contact fabricated only using evaporation, five devices failed. That is, five devices developed sudden short circuits upon being tested upon increasing the voltage. In contrast, when the ITO contacts are made with evaporation followed by sputtering, all 11 devices passed under the same test conditions.

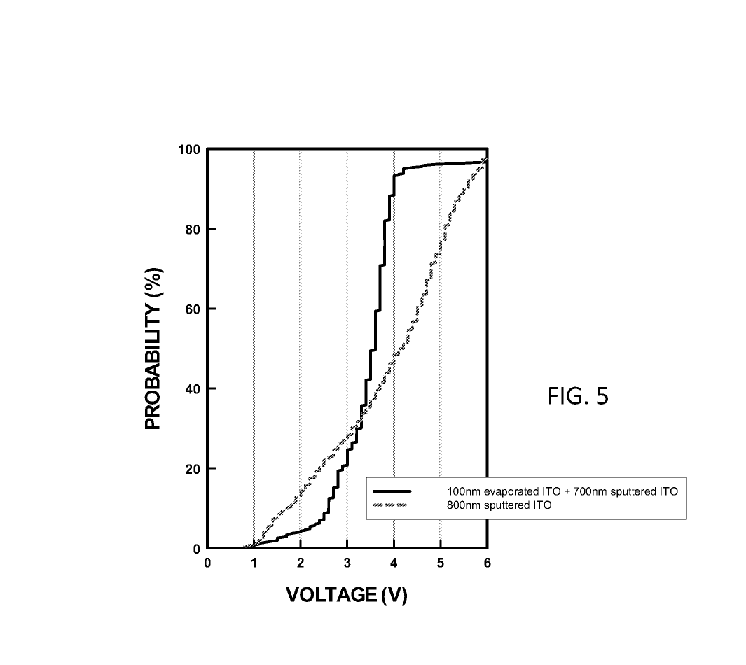

FIG. 5 is a probability plot of the voltage (V_{F}) at 1 mA current for two substrates with approximately 500 devices tested on each substrate. The devices in which the ITO contact (i.e., electrode) was made by a combination of evaporation (100 nm thick) and sputtering (700 nm thick) shows a much tighter distribution of voltage and a lower median voltage (V_{f}) than the devices in which the ITO contact (800 nm thick) was made by evaporation only. Both tight distribution and low V_{f} are desirable for the manufacture of light emitting diodes. In general, evaporated ITO has been shown to make a good ohmic contact to p-type GaN, whereas sputtered ITO or other transparent conductive films deposited by chemical vapor often have non ohmic contacts to p-type GaN. However, the sputtered or chemical vapor deposited TCFs can produce denser films with better step coverage over 3D features compared to evaporated films.

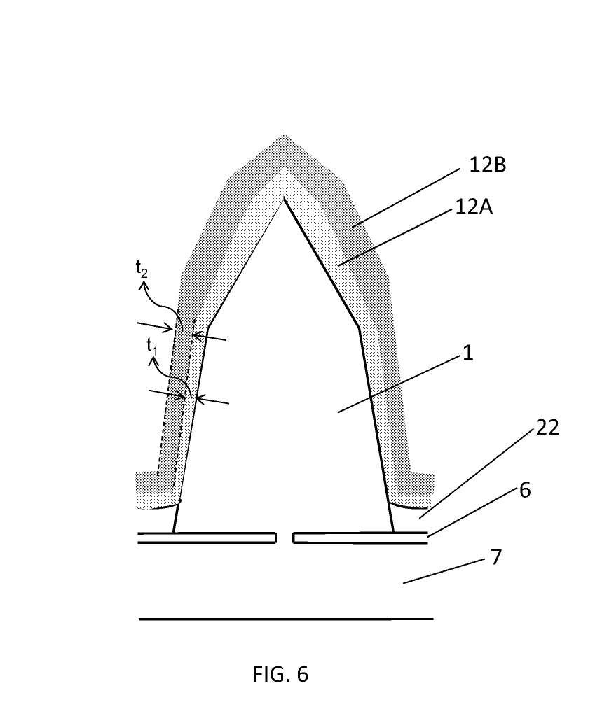

In another embodiment, an evaporated ITO layer 12A having a midpoint thickness, t₁ of 200 nm is deposited on nanowires, followed by chemical vapor deposition of a fluorine-doped tin oxide (FTO) layer 12B having a midpoint thickness, t₂ of 400 nm over layer 12A, as shown in FIG. 6. This combination has good density compared to the evaporated ITO-only shown in FIG. 3A. In an alternative embodiment, the second layer 12B is indium tin oxide (ITO) while the first layer 12A is a transparent conductive film (TCF) of a different composition.

In another embodiment illustrated in FIG. 6, the transparent conducting film (TCF) has a density that varies through the thickness of the film on the sidewall. This embodiment may provide the best combination of low contact resistance and low sheet resistance. The density of the TCF varies in the thickness of the film, with the material closest to the GaN nanowire 1 surface having the lowest density, and the material on the free surface of the film farthest from the GaN nanowire surface having the highest density. As illustrated in FIG. 6, the thickness of the composite film 12A+12B on the sidewall of the nanowire 1 is t, where t is measured normal to the nanowire sidewall surface, then the density of the material in layer 12A is lower than the density of the material in layer 12B. If the TCF has a theoretical maximum density x (based on its crystal structure), an optical TCF film for nanowires might have a density of 0.3x-0.6x, such as 0.5x for layer 12A, and a density of 0.65x-0.9x, such as 0.8x for layer 12B. In an embodiment, the thickness t₁ of layer 12A is smaller than thickness t₂ of layer 12B, preferably t₁<0.1(t₂), such as t₁=0.01 to 0.9(t₂).

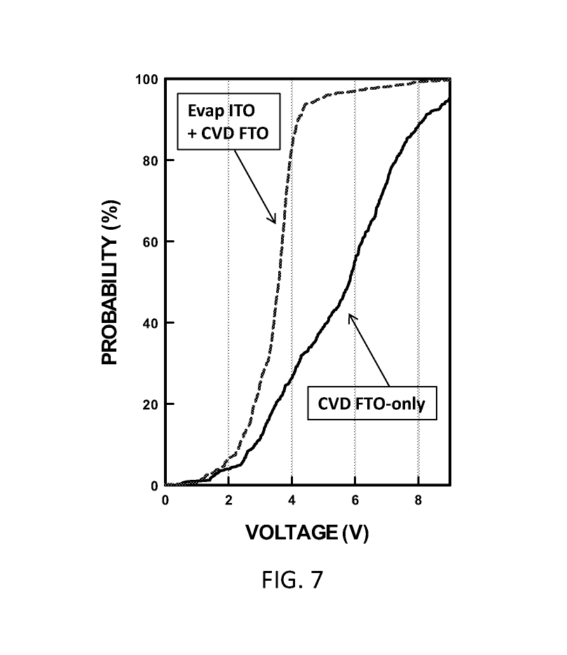

FIG. 7 shows a probability plot of the voltage at 10mA for about 1000 devices composed of nanowire LEDs, where 500 devices have p contacts composed of 200 nm of evaporated ITO+400 nm of CVD FTO, and 500 devices have p contacts composed of CVD FTO-only. The median voltage of the devices with the combined evaporated ITO+CVD FTO films is lower than those for CVD FTO films only.

While ITO electrodes on p-GaN shells are described above, it should be noted that any transparent conductive oxide (TCO), such as ZnO, doped ZnO (e.g. FTO (fluorine-doped tin oxide)), aluminum oxide, doped aluminum oxide (e.g. AZO (aluminum zinc oxide)), indium oxide, tin oxide, etc., may be formed using the two step evaporation followed by sputtering method. Furthermore, while the contact is described above as being formed on a p-GaN shell of a core-shell nanowire device, the transparent conductive oxide layer may be formed on any p-type or n-type III-nitride semiconductor surface of a nanostructured device. For example, the contact layer may be formed on p-type or n-type AlGaN or InGaN material. Still further, the nanostructured device is not limited to a radial nanowire device 1 having a nanowire core 2 with a nanowire or bulk shell 3. The device may comprise a longitudinal nanowire device having elongated semiconductor regions contacting each other end to end or any other nanostructured device having III-nitride semiconductor nanostructure (e.g., nano-belt—a ribbon-like structure which typically have widths of 30-300 nm, thicknesses of 10-30 nm, and lengths in the millimeter range and which may jut out from the surface of the substrate in a manner similar to nanowires; or nano-rail—a nanostructure whose entire length lies on the surface of the substrate; or another nano scale protrusion) extending from a support surface. The nano-protrusions may be grown on the support surface, deposited on the support surface or etched into the support surface.

Although the present invention is described in terms of contacting of nanowire LEDs, it should be appreciated that other nanowire based semiconductor devices, such as field-effect transistors, diodes and, in particular, devices involving light absorption or light generation, such as, photodetectors, solar cells, lasers, etc., can be implemented on any nanowire structures.

All publications and patents cited in this specification are herein incorporated by reference as if each individual publication or patent were specifically and individually indicated to be incorporated by reference and are incorporated herein by reference to disclose and describe the methods and/or materials in connection with which the publications are cited. The citation of any publication is for its disclosure prior to the filing date and should not be construed as an admission that the present invention is not entitled to antedate such publication by virtue of prior invention. Further, the dates of publication provided may be different from the actual publication dates which may need to be independently confirmed.

What is claimed is:

1. A method of making a semiconductor device, comprising:
depositing a first transparent conductive film (TCF) contact layer on a sidewall of a III-nitride semiconductor nanostructure by evaporation; and
depositing a second TCF contact layer over the first TCF contact layer by sputtering or chemical vapor deposition (CVD).

2. The method of claim 1, wherein the TCF comprises a transparent conductive oxide.

3. The method of claim 1, wherein:
the nanostructure comprises a III-nitride semiconductor shell surrounding a III-nitride semiconductor nanowire core; and
the first and the second TCF contact layers comprise indium tin oxide (ITO) layers.

4. The method of claim 1, where the first layer comprises indium tin oxide (ITO), and the second layer is a transparent conductive film (TCF) of a different composition.

5. The method of claim 1, where the second layer comprises indium tin oxide (ITO), and the first layer is a transparent conductive film (TCF) of a different composition.

6. The method of claim 1, where the second film is deposited by chemical vapor deposition and is composed of doped ZnO or doped SnO₂.

7. The method of claim 2, wherein the device comprises an array of LED devices, each nanostructure comprises a LED device, and the III-nitride shell comprises a p-GaN shell.

8. The method of claim 1, wherein the first TCF contact layer is thinner than the second TCF contact layer.

9. A semiconductor device made by the method of claim 1.

10. A semiconductor device, comprising:
a plurality of upstanding III-nitride nanostructures on a support; and
an upper contact over ends of the nanostructures located distal from the substrate,
wherein the upper contact comprises a first evaporated transparent conductive film (TCF) contact layer on the III-nitride nanostructures and a second sputtered or CVD deposited TCF contact layer on the first TCF contact layer.

11. The device of claim 10, wherein the first and the second TCF contact layers comprise transparent conductive oxide (TCO) layers.

12. The device of claim 11, wherein:
the nanostructure comprises a III-nitride semiconductor shell surrounding a III-nitride semiconductor nanowire core; and
the first evaporated TCF contact layer and the second sputtered or CVD deposited TCF contact layer comprise ITO layers.

13. The device of claim 11, wherein:
the nanostructure comprises a III-nitride semiconductor shell surrounding a III-nitride semiconductor nanowire core; and
the first evaporated TCF contact layer and the second sputtered or CVD deposited TCF contact layer have different compositions.

14. The device of claim 12, wherein the device comprises an array of LED devices, each nanostructure comprises a LED device, and the III-nitride shell comprises a p-GaN shell.

15. The device of claim 10, wherein the first evaporated TCF contact layer is thinner than the second sputtered or CVD deposited TCF contact layer.

16. The device of claim 10, wherein the plurality of upstanding III-nitride nanostructures on a support comprise:
a plurality of n-type semiconductor nanowire cores located over a support;
an insulating mask layer located over the support, wherein the nanowire cores comprise semiconductor nanowires epitaxially extending from portions of a semiconductor surface of the support exposed through openings in the insulating mask layer; and
a plurality of p-type GaN semiconductor shells extending over and around the respective nanowire cores.

17. The device of claim 11, wherein the first and the second TCF contact layers comprise indium tin oxide (ITO), doped zinc oxide or doped tin oxide.

18. The device of claim 11, wherein the first TCF contact layer comprises evaporated ITO and the second TCF contact layer comprises sputtered ITO.

19. The device of claim 11, wherein the first TCF contact layer comprises evaporated ITO and the second TCF contact layer comprises CVD deposited fluorine doped tin oxide.

20. A method of making a semiconductor device, comprising:
depositing a first transparent conductive film (TCF) contact layer on a sidewall of a III-nitride semiconductor nanostructure; and
depositing a second TCF contact layer over the first TCF contact layer,
wherein a density of the first TCF contact layer is less than a density of the second contact layer.

21. The method of claim 20, wherein a thickness of the first TCF contact layer is less than a thickness of the second contact layer.

22. The method of claim 21, wherein the thickness of the first TCF contact layer is less than 0.1 times the thickness of the second contact layer.

23. A semiconductor device, comprising:
a plurality of upstanding III-nitride nanostructures on a support; and
an upper contact over ends of the nanostructures located distal from the substrate,
wherein the upper contact comprises a first transparent conductive film (TCF) contact layer on the III-nitride nanostructures and a second TCF contact layer on the first TCF contact layer, and
wherein a density of the first TCF contact layer is less than a density of the second contact layer.

24. The device of claim 23, wherein a thickness of the first TCF contact layer is less than a thickness of the second contact layer.

25. The device of claim 24, wherein the thickness of the first TCF contact layer is less than 0.1 times the thickness of the second contact layer.
